(19) United States
(12) Patent Application Publication
(10) Pub. No.: US 2012/0322273 A1
(43) Pub. Date: Dec. 20, 2012

(54) COATING FILM FORMING METHOD AND COATING FILM FORMING APPARATUS

(75) Inventor: Tomoya OORI, Mie (JP)

(73) Assignee: Kabushiki Kaisha Toshiba, Tokyo (JP)

(21) Appl. No.: 13/357,775

(22) Filed: Jan. 25, 2012

(30) Foreign Application Priority Data
Jun. 14, 2011 (JP) 2011-132326

(51) Int. Cl. H01L 21/31; B05C 5/02

(52) U.S. Cl. 438/765; 118/302; 257/E21.24

(57) ABSTRACT

A coating film forming method according to an embodiment, includes rotating a substrate, supplying a chemical solution for forming a coating film onto the rotating substrate, and supplying a liquid having a lower temperature than an atmosphere of the substrate to an edge of the substrate from a back side of the substrate while a film is formed by supplying the chemical solution onto the rotating substrate.

### CROSS-REFERENCE TO RELATED APPLICATION

This application is based upon and claims the benefit of priority from Japanese Patent Application No. 2011-132326 filed on Jun. 14, 2011 in Japan, the entire contents of which are incorporated herein by reference.

### FIELD

Embodiments described herein relate generally to a coating film forming method and a coating film forming apparatus.

### BACKGROUND

In the fabrication of semiconductor devices, improvement in productivity has been sought by acquiring as many chips as possible from one silicon wafer. One method of improving the productivity is to enlarge a region (valid region) that can be used as a semiconductor substrate on a wafer. However, a region (invalid region) of several millimeters in which no pattern is formed is set in a peripheral portion of a silicon wafer and due to the invalid region of several millimeters, a chip that would be within a wafer diameter without the invalid region may be set as an invalid chip.

One cause of such an invalid region being set is that it is difficult for film formation using a rotating coating method to control the thickness of a film in a peripheral portion of a wafer. That is, a film formed by the rotating coating method tends to be thicker in the peripheral portion than in a center portion. When such a film thick in the peripheral portion is left, if a coating film is, for example, an antireflection film formed below a resist film, exposure conditions for photolithography may fluctuate, leading to degradation in pattern shape. Thus, several millimeters from the edge of the peripheral portion of a wafer where the film tends to be thick is removed by, for example, performing thinner cutting processing using a solvent. To acquire more valid chips, it is desirable to control the thickness of a film in the peripheral portion of a wafer to make the region where such a film is removed smaller.

### BRIEF DESCRIPTION OF THE DRAWINGS

FIG. 1 is a flow chart showing principal processes of a coating film forming method according to a first embodiment;

FIG. 2 is a diagram showing the configuration of a coating film forming apparatus according to the first embodiment;

FIG. 3 is a diagram exemplifying a film thickness in a peripheral portion of a substrate to make comparison with the first embodiment;

FIGS. 4A and 4B are conceptual diagrams illustrating a difference in film thickness in the peripheral portion between when the peripheral portion on a back side of the substrate is cooled in the first embodiment and when the peripheral portion is not cooled; and

FIG. 5 is a diagram illustrating an operation of the coating film forming apparatus that performs thinner cutting and back-side rinse in the first embodiment.

### DETAILED DESCRIPTION

A coating film forming method according to an embodiment, includes rotating a substrate, supplying a chemical solution for forming a coating film onto the rotating substrate, and supplying a liquid having a lower temperature than an atmosphere of the substrate to an edge of the substrate from a back side of the substrate while a film is formed by supplying the chemical solution onto the rotating substrate.

A coating film forming apparatus according to an embodiment, includes a stage, a first supplying nozzle, a second supplying nozzle, and a temperature control device. The stage is configured to place a substrate thereon to rotate the substrate. The first supplying nozzle is configured to supply a chemical solution for forming a coating film onto the rotating substrate from above. The second supplying nozzle is configured to supply a liquid to an edge of the substrate from a back side of the rotating substrate. The temperature control device is configured to control a temperature of the liquid supplied from the second supplying nozzle.

### First Embodiment

In the first embodiment, a coating film forming method and a coating film forming apparatus capable of enlarging a valid region of a substrate by controlling the thickness of a coating film in a peripheral portion of the substrate will be described below. The first embodiment will be described below using the drawings.

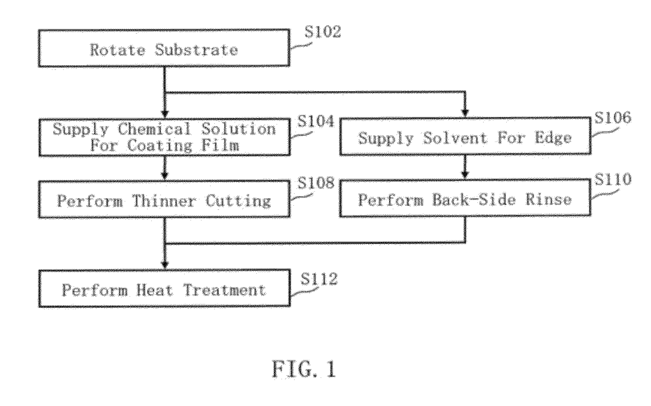

FIG. 1 is a flow chart showing principal processes of the coating film forming method according to the first embodiment. In FIG. 1, the coating film forming method according to the first embodiment carries out a series of processes including a substrate rotation process (S102), a coating film chemical solution supplying process (S104), an edge solvent supplying process (S106), a top surface thinner cutting process (S108), a back-side rinse process (S110), and a heat treatment process (S112).

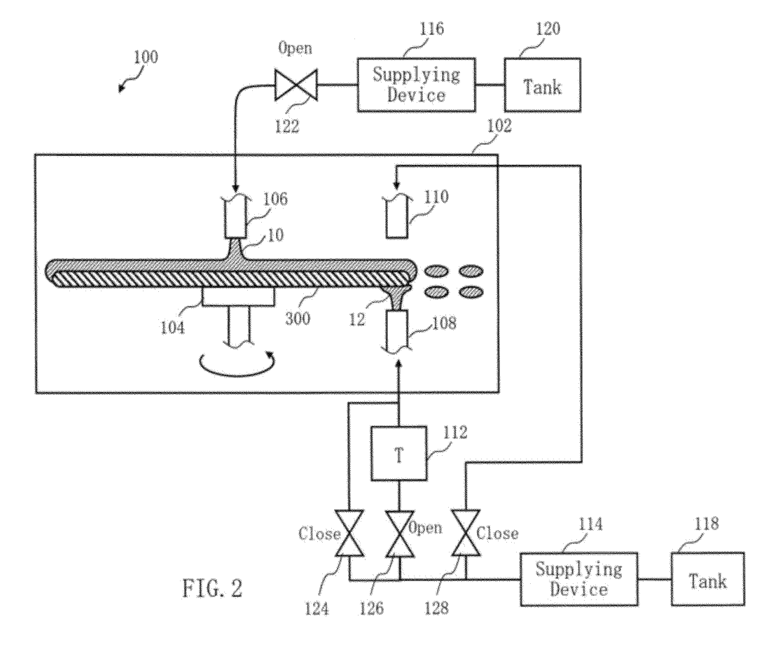

The configuration of a coating film forming apparatus according to the first embodiment is shown in FIG. 2. In FIG. 2, a coating film forming apparatus 100 according to the first embodiment includes a chamber 102, a stage 104, supplying nozzles 106, 108, and 110, a temperature control device 112, chemical liquid supplying devices 114 and 116, chemical liquid tanks 118 and 120, and valves 122, 124, 126, and 128. The stage 104 is rotatably arranged inside the chamber 102. The stage 104 has a substrate 300 placed thereon, on the front side of which a coating film is to be formed. The stage 104 chucks the back side of the substrate 300 by, for example, vacuum-absorbing a center portion of the back side of the substrate 300. When the substrate 300 is placed on the stage 104, the center point on the front side of the substrate 300 is positioned on a rotation axis of the stage 104.

As the substrate rotation process (S102), the substrate 300 with its center placed on the axis is rotated by rotating the stage 104 using the center of the stage 104 as the axis while the center portion of the back side of the substrate 300 is chucked (fixed). The number of revolutions is set so that, for example, the thickness of a coating film after the subsequent calcination (heating process) and cooling becomes about 100 nm. Though depending on the viscosity of chemical solution of the coating film, the number of revolutions is suitably set to, for example, 1200 to 1800 min⁻¹ (rpm). In this case, the number of revolutions when a chemical solution for forming a coating film is dripped onto the substrate 300 and the number of revolutions when drying processing is performed after the dripping also to adjust the thickness of the film may suitably be changed.

As the coating film chemical solution supplying process (S104), a chemical solution for forming a coating film is supplied or “fed” onto the rotating substrate. More specifically, the supplying device 116 sends a chemical solution for forming a coating film from the tank 120 filled with the chemical solution for forming a coating film toward the nozzle 106 to supply a chemical solution 10 for forming a coating film from the nozzle 106 (first supplying nozzle) arranged above the substrate 300 to the center on the front side of the substrate 300 by switching the valve 122 from Close to Open. If, for example, a resist film is formed as a coating film, a chemical solution for the resist film is supplied.

If the film is formed directly by drying the chemical solution 10 on the substrate 300, the thickness of the coating film formed in a peripheral portion of the substrate 300 will be thicker than the thickness of the film formed outside the peripheral portion. This is because, if the substrate 300 is rotated, the peripheral portion of the substrate 300 has a higher speed than the center portion and a heat exchange occurs correspondingly so that a solvent of the chemical solution 10 is more likely to be dried and solidified in the peripheral portion. Thus, the action is repeated in which the chemical solution 10 supplied to the center portion successively moves toward a film starting to be solidified in the peripheral portion, the chemical solution 10 moving from the center portion covers the film starting to be solidified in the peripheral portion, and the film is dried and solidified while being covered. Therefore, in the first embodiment, the following process is carried out in parallel with the coating film chemical solution supplying process (S104).

As the edge solvent supplying process (S106), the chemical solution 10 for forming a coating film described above is supplied onto the rotating substrate 300 and at the same time, a liquid having a lower temperature than the atmosphere of the substrate 300 is supplied to edges of the substrate 300 from the back side of the substrate 300. More specifically, the supplying device 114 sends a solvent from the tank 118 filled with the solvent of the chemical solution for forming a coating film toward the nozzle 108 to supply the solvent to the temperature control device 112 by switching the valve 126 from Close to Open with the valves 124 and 128 closed. Then, the temperature of the solvent is cooled to a temperature lower than the temperature of the atmosphere of the substrate 300 by the temperature control device 112. After the solvent is cooled, a cooled solvent 12 (coolant) is locally supplied from the nozzle 108 (second supplying nozzle) arranged on the back side of the peripheral portion of the substrate 300 toward the peripheral portion on the back side of the substrate 300. In this manner, the temperature control device 112 (temperature control unit) controls the temperature of the liquid supplied from the nozzle 108. The coolant is suitably supplied a little to the side of the center portion from a region of the peripheral portion of the substrate 300 where the film becomes thicker. For example, the coolant is preferably supplied to the side of the center portion about 5 mm from the edge of the substrate 300. Accordingly, the region where the film becomes thick can reliably be cooled. As described above, the valve 126 (first valve) is arranged between the supplying device 114 and the temperature control device 112 to perform a switching operation of a channel leading to the nozzle 108 from the supplying device 114 via the temperature control device 112.

With the above operation, the temperature of the peripheral portion of the substrate 300 falls so that the saturated vapor pressure of the peripheral portion on the front side of the substrate 300 can be lowered. As a result, drying of the chemical solution for forming a coating film in the peripheral portion of the substrate can be delayed. Thus, a chemical solution flowing from the center portion due to a centrifugal force is also caused to flow in the peripheral portion in the same manner as in the center portion and an excessive chemical solution flies, or “scatter” to the outside from the edge of the substrate 300. Also on the back side of the substrate 300, the coolant cools the peripheral portion on the back side of the substrate 300 before being flown to the outside by the centrifugal force. As a result, the thickness of a coating film can be inhibited from being thickened in the peripheral portion of the substrate 300.

If, for example, a resist film is formed as a coating film, cyclohexanone or propylene glycol monomethyl ether acetate (PGMEA) can be cited as a solvent of the resist material. If, for example, an SOG (spin on glass) film is formed as a coating film, cyclohexanone or gamma butyrolactone can be cited as a solvent of the SOG material. If, for example, an immersion protection film is formed as a coating film, METHYL ISOBUTYL CARBINOL (MIBC) can be cited as a solvent of the immersion protection film material. In the above examples, a solvent of the chemical solution for forming a coating film is used as an example of the coolant supplied in the edge solvent supplying process (S106), but the present embodiment is not limited to such examples. Any liquid capable of cooling the peripheral portion of the substrate 300 from the back side may be used.

Any temperature of the coolant supplied to the peripheral portion on the back side of the substrate 300 has an effect as long as the temperature is lower than the temperature of the atmosphere of the substrate 300. As the lower limit of the temperature, on the other hand, it is desirable to set a temperature at which no condensation occurs. When a chemical solution for forming a coating film is at room temperature, the temperature of the coolant is desirably, for example, about 10° C. to 15° C.

The coolant may be supplied to the peripheral portion on the back side of the substrate 300 while a chemical solution for forming a coating film is dripped (fed or supplied). Alternatively, after a chemical solution for forming a coating film is supplied to form a liquid film on the front side of the substrate 300, the coolant may be supplied to the peripheral portion on the back side of the substrate 300 while the chemical solution that has become the liquid film is dried to a film of a predetermined thickness fixed on the substrate by increasing the number of revolutions. Alternatively, both may be performed. That is, it is only necessary to cool from the peripheral portion on the back side of the substrate 300 before a chemical solution in the peripheral portion of the substrate 300 being dried for the formation of a coating film. Accordingly, the saturated vapor pressure can be lowered before a chemical solution is dried in the peripheral portion of the substrate.

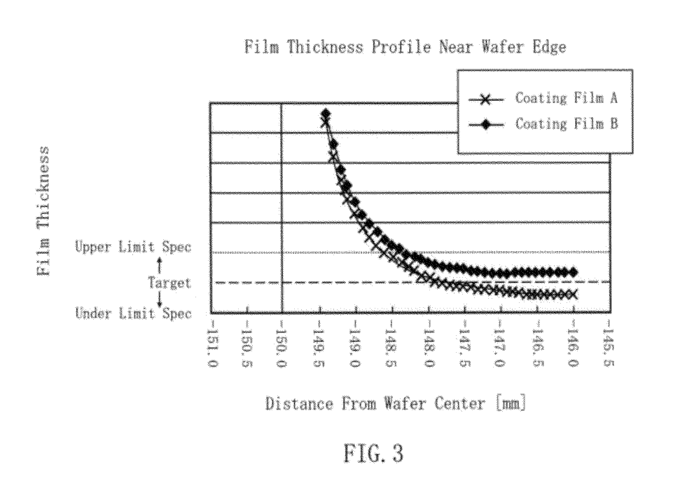

FIG. 3 exemplifies the film thickness in a peripheral portion of a substrate to make comparison with the first embodiment. Here, a case where a wafer of 300 mm is used is shown. It is found that, if the peripheral portion on the back side of a substrate is not cooled unlike in the first embodiment, as shown in FIG. 3, the film thickness increases from the vicinity of 4 mm from the edge of the substrate (146 mm from the center of the substrate) toward the peripheral portion. Thus, when a chip is formed, for example, a region from the edge of a substrate to about 4 mm inward becomes an invalid region of a wafer.

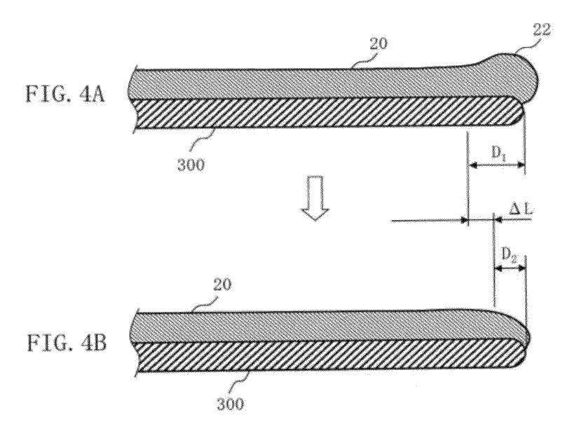

FIGS. 4A and 4B are conceptual diagrams illustrating a difference in film thickness in the peripheral portion between when the peripheral portion on the back side of the substrate is cooled in the first embodiment and when the peripheral portion is not cooled. If a coating film is formed without the peripheral portion on the back side of a substrate being cooled, as shown in FIG. 4A, the thickness of a coating film 22 in the peripheral portion becomes thicker than the thickness of a coating film 20 in a region other than the peripheral portion on the substrate 300. Thus, if a coating film is formed without the peripheral portion on the back side of a substrate being cooled, as shown in FIG. 4A, no chip can be formed in a portion where the film is thick and it is unavoidable to set a region of D1 from the edge as an invalid region.

In contrast, if a coating film is formed while the peripheral portion on the back side of a substrate is cooled like in the first embodiment, as shown in FIG. 4B, control can be exercised so that the film in the peripheral portion of the substrate 300 does not become thick. Thus, if a coating film is formed while the peripheral portion on the back side of a substrate is cooled, as shown in FIG. 4B, a region of D2 from the edge of a portion of a bevel portion of the substrate 300 where the film becomes thin can be set as an invalid region. As a result, the valid region of the substrate can be enlarged by ΔL. Then, for such an invalid region, the film is removed by thinner cutting as will be described below.

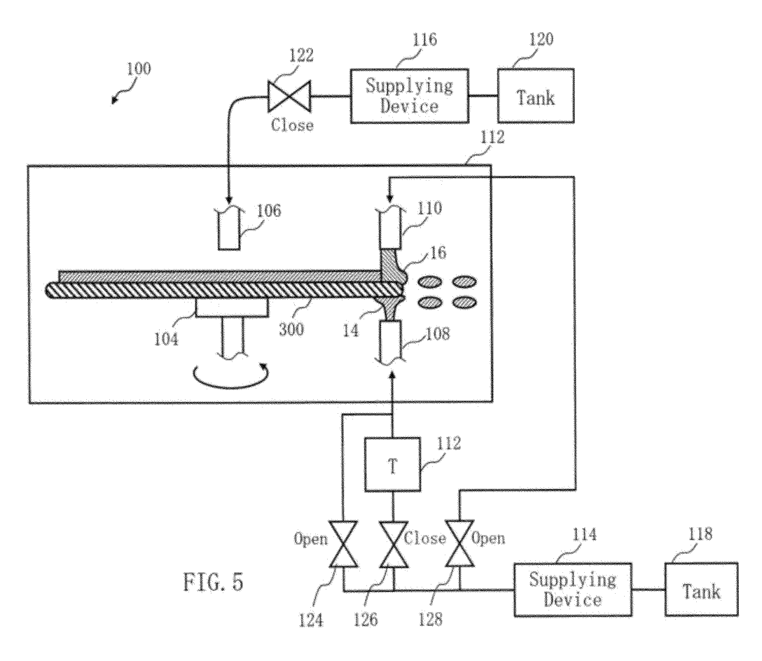

FIG. 5 is a diagram illustrating an operation of the coating film forming apparatus that performs thinner cutting and back-side rinse in the first embodiment.

As the top surface thinner cutting process (S108), after the substrate 300 is coated with the chemical solution, a solvent of the chemical solution for forming a coating film is supplied to a portion to be an invalid region at an edge of the substrate 300 from above the substrate 300 while the substrate 300 is rotated. More specifically, the supplying device 114 sends a solvent from the tank 118 filled with the solvent of the chemical solution for forming a coating film toward the nozzle 110 to supply a non-cooled solvent 16 from the nozzle 110 arranged on the front side (upper side) of the peripheral portion of the substrate 300 toward the peripheral portion on the front side of the substrate 300 by switching the valve 128 from Close to Open with the valve 126 closed. Accordingly, films formed in a bevel portion or the like of the substrate 300 with different thickness can be removed. In the past, as shown in FIG. 3, the film thickness in a region of about 4 mm from the edge of a substrate becomes thick and thus, it is necessary to remove a film of, for example, about 5 mm from the edge of the substrate. In the first embodiment, by contrast, it is only necessary to remove a film of 1 mm or less from the edge of a substrate. It is enough to remove a film of, for example, about 0.6 mm. In the top surface thinner cutting process (S108), back-side rinse is performed simultaneously.

As the back-side rinse process (S110), after the substrate 300 is coated with the chemical solution, the back-side rinse is performed on the edge of the substrate 300 from the back side of the substrate 300 while the substrate 300 is rotated. More specifically, the supplying device 114 sends a solvent from the tank 118 filled with the solvent of the chemical solution for forming a coating film toward the nozzle 108 to supply a non-cooled solvent 14 from the nozzle 108 arranged on the back side of the peripheral portion of the substrate 300 toward the peripheral portion on the back side of the substrate 300 by switching the valve 124 from Close to Open with the valve 126 closed. Accordingly, flying portions during thinner cutting can be prevented from adhering to the edge on the back side of the substrate or adhered particles can be removed. If, for example, the coolant in the edge solvent supplying process (S106) is not a solvent of the chemical solution for forming a coating film, the chemical solution may move around to the back side of the substrate to form a film when a coating film is formed. Also in such a case, the film formed by the chemical solution moved around to the back side of the substrate can be removed by performing the back-side rinse with a solvent. Because the supply liquid for the back-side rinse process (S110) is supplied without being cooled, the liquid has a higher temperature than the supply liquid for the edge solvent supplying process (S106). If such a high-temperature liquid is used, a film formed on the back side of the substrate is more likely to be dissolved in a solvent so that the film can be removed more easily. As described above, the valve 124 (second valve) is arranged between the supplying device 114 and the nozzle 108 to perform a switching operation of a channel leading to the nozzle 108 from the supplying device 114 without passing through the temperature control device 112.

As the heat treatment process (S112), a coating film is completed by heat treatment (calcination) of the fixed coating film. For example, the substrate 300 coated with a resist film is calcined on a hot plate at 100° C. Then, the resist film of a desired thickness can be obtained by cooling the resist film on a chill plate at 23° C.

In the above coating film forming apparatus, an example in which the supply liquid of the top surface thinner cutting process (S108), the supply liquid of the back-side rinse process (S110), and the supply liquid of the edge solvent supplying process (S106) are supplied from the same source, but the present embodiment is not limited to such an example. The supply liquid may be supplied from different sources partially or totally. It is only necessary that a temperature control device capable of cooling be arranged on a path through which the supply liquid for the edge solvent supplying process (S106) is supplied to the peripheral portion on the back side of the substrate. Also an example in which the supplying nozzle for the back-side rinse process (S110) and the supplying nozzle for the edge solvent supplying process (S106) are shared is shown, but the present embodiment is not limited to such an example. Different nozzles may be used for supplying. Further, an example in which a film in an invalid region of a wafer is removed by thinner cutting is shown, but if a resist film made of a positive resist material is formed as a coating film, a film in an invalid region of a wafer may be removed by circumference exposure near a peripheral portion of a substrate and subsequent development.

According to the first embodiment, as described above, controllability of the film thickness of a chemical solution in the peripheral portion of a substrate can be improved by delaying drying of the peripheral portion of the substrate.

The embodiment has been described above with reference to the concrete examples. However, the embodiment is not limited to the concrete examples.

Chemical solutions for forming a coating film and solvents of chemical solutions that are needed for the formation of the coating film can appropriately be selected and used.

In addition, all coating film forming apparatuses and coating film forming methods which include the elements of the present embodiment and can be attained by appropriately changing in design by a person skilled in the art are included in the spirit and scope of the embodiment.

Techniques normally used for semiconductor production, for example, cleaning before and after processing are omitted for the simplification of description, but it is needless to say that such techniques are included in the spirit and scope of the embodiment.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods, apparatuses and devices described herein may be made without departing from the spirit of the inventions. The accompanying claims and their equivalents are intended to cover such forms or modifications as would fall within the scope and spirit of the inventions.

What is claimed is:

1. A coating film forming method, comprising:
rotating a substrate;
supplying a chemical solution for forming a coating film onto the rotating substrate; and
supplying a liquid having a lower temperature than an atmosphere of the substrate to an edge of the substrate from a back side of the substrate while a film is formed by supplying the chemical solution onto the rotating substrate.

2. The method according to claim 1, wherein a solvent of the chemical solution is used as the liquid.

3. The method according to claim 1, further comprising:
after the substrate is coated with the chemical solution, performing back-side rinse of the edge of the substrate from the back side of the substrate while the substrate is rotated.

4. The method according to claim 3, wherein a solvent of the chemical solution is used for the back-side rinse.

5. The method according to claim 3, wherein a liquid having a higher temperature than the liquid having the lower temperature is used for the back-side rinse.

6. The method according to claim 1, further comprising:
after the substrate is coated with the chemical solution, performing thinner cutting of the edge of the substrate from a top surface side of the substrate while the substrate is rotated.

7. The method according to claim 6, wherein a solvent of the chemical solution is used for the thinner cutting.

8. The method according to claim 6, wherein a liquid having a higher temperature than the liquid having the lower temperature is used for the thinner cutting.

9. The method according to claim 6, further comprising:
performing back-side rinse of the edge of the substrate from the back side of the substrate simultaneously with the thinner cutting.

10. The method according to claim 9, wherein a solvent of the chemical solution is used for the thinner cutting and the back-side rinse.

11. The method according to claim 9, wherein a liquid having a higher temperature than the liquid having the lower temperature is used for the thinner cutting and the back-side rinse.

12. The method according to claim 1, wherein the liquid having the lower temperature is cooled by a temperature control device.

13. The method according to claim 1, further comprising:
performing heat treatment for the coating film obtained after the liquid having the lower temperature is supplied from the back side of the substrate to the edge of the substrate.

14. The method according to claim 13, wherein the heat treatment is performed after thinner cutting of the edge of the substrate performed from a top surface side of the substrate to remove the coating film at the edge of the substrate.

15. The method according to claim 14, wherein back-side rinse of the edge of the substrate from the back side of the substrate is performed simultaneously with the thinner cutting.

16. A coating film forming apparatus, comprising:
a stage configured to place a substrate thereon to rotate the substrate;
a first supplying nozzle configured to supply a chemical solution for forming a coating film onto the rotating substrate from above;
a second supplying nozzle configured to supply a liquid to an edge of the substrate from a back side of the rotating substrate; and
a temperature control device configured to control a temperature of the liquid supplied from the second supplying nozzle.

17. The apparatus according to claim 16, further comprising:
a third supplying nozzle configured to supply a liquid to the edge of the substrate from a top surface side of the rotating substrate.

18. The apparatus according to claim 16, further comprising:
a supplying device configured to supply the liquid to the second supplying nozzle.

19. The apparatus according to claim 18, further comprising:
a first valve arranged between the supplying device and the temperature control device to perform a switching operation of a channel leading to the second supplying nozzle from the supplying device via the temperature control device.

20. The apparatus according to claim 19, further comprising:
a second valve arranged between the supplying device and the second supplying nozzle to perform a switching operation of a channel leading to the second supplying nozzle from the supplying device without passing through the temperature control device.
